(19) United States
(12) Patent Application Publication
(10) Pub. No.: US 2026/0190632 A1
(43) Pub. Date: Jul. 2, 2026

(54) DISPLAY PANEL AND ELECTRONIC DEVICE

(71) Applicant: Hubei Yangtze Industrial Innovation Center of Advanced Display Co., LTD., Wuhan (CN)

(72) Inventor: Yuehua YANG, Wuhan (CN)

(21) Appl. No.: 19/077,545

(22) Filed: Mar. 12, 2025

(30) Foreign Application Priority Data
Dec. 31, 2024 (CN) 202411990863.8

(51) Int. Cl. H10K 59/122; H10K 59/38; H10K 59/80

(52) U.S. Cl. CPC H10K 59/122; H10K 59/38; H10K 59/80515; H10K 59/80521; H10K 59/879; H10K 59/8792

(57) ABSTRACT

A display panel and an electronic device are provided. The display panel include a substrate; an anode layer located on the substrate and including anode blocks; a first pixel definition layer located on a side of the anode layer away from the substrate and including a first pixel opening; an electrode connection layer located on a side of the pixel definition layer away from the substrate and including a second pixel opening; a second pixel definition layer located on a side of the electrode connection layer away from the substrate and including a third pixel opening; a light-emitting functional layer including first portions second portions, a cathode layer including a first cathode portion and a second cathode portion; and a second inorganic film is located on a side of the first inorganic film away from the substrate and covering the first inorganic film.

### CROSS-REFERENCE TO RELATED APPLICATION

This application claims the priority of Chinese Patent Application No. 202411870027.6, filed on Dec. 18, 2024, the content of which is incorporated by reference in its entirety.

### TECHNICAL FIELD

The present disclosure generally relates to the field of display technologies and, more particularly, relates to a display panel and an electronic device.

### BACKGROUND

Organic light-emitting diode (OLED) is an active light-emitting device. Compared with the traditional liquid crystal display (LCD) display method, OLED display technology does not require a backlight and has the characteristic of self-luminescence. OLED uses a thinner organic material layer to form a light-emitting device. When an electric current passes through the organic material layer, the organic material will emit light. OLED display panels have the advantages of saving energy, and can be made lighter and thinner. In addition, OLED display panels can withstand a wider range of temperature than LCD display panels and have a larger viewing angle. OLED display panels are one of the most popular technologies in flat panel display technology.

Although OLED display panels have many advantages, there are some issues in the packaging reliability of OLED display panels today, which needs further improvement. The present disclosed display panels and electronic devices are direct to solve such problems and other problems in the arts.

### SUMMARY

One aspect of the present disclosure provides a display panel. The display panel includes a substrate; an anode layer located on the substrate and including a plurality of anode blocks; a first pixel definition layer located on a side of the anode layer away from the substrate and including a first pixel opening corresponding to an anode block of the plurality of anode blocks; an electrode connection layer located on a side of the pixel definition layer away from the substrate and including a second pixel opening corresponding to the first pixel opening; a second pixel definition layer located on a side of the electrode connection layer away from the substrate and including a third pixel opening corresponding to the second pixel opening; and a light-emitting functional layer including a plurality of first portions and a plurality of second portions. A first portion of the plurality of first portions is at least located in the first pixel opening, and a second portion of the plurality of second portions at least covers a sidewall of the third pixel opening. The display panel also includes a cathode layer including a first cathode portion and a second cathode portion; a first inorganic film located on a side of the cathode layer away from the substrate; and a second inorganic film is located on a side of the first inorganic film away from the substrate and covering the first inorganic film. The first cathode portion covers the first portion and extends to contact the electrode connection layer.

Another aspect of the present disclosure provides an electronic device. The electronic device includes a display panel. The display panel includes a substrate; an anode layer located on the substrate and including a plurality of anode blocks; a first pixel definition layer located on a side of the anode layer away from the substrate and including a first pixel opening corresponding to an anode block of the plurality of anode blocks; an electrode connection layer located on a side of the pixel definition layer away from the substrate and including a second pixel opening corresponding to the first pixel opening; a second pixel definition layer located on a side of the electrode connection layer away from the substrate and including a third pixel opening corresponding to the second pixel opening; and a light-emitting functional layer including a plurality of first portions and a plurality of second portions. A first portion of the plurality of first portions is at least located in the first pixel opening, and a second portion of the plurality of second portions at least covers a sidewall of the third pixel opening. The display panel also includes a cathode layer including a first cathode portion and a second cathode portion; a first inorganic film located on a side of the cathode layer away from the substrate; and a second inorganic film is located on a side of the first inorganic film away from the substrate and covering the first inorganic film. The first cathode portion covers the first portion and extends to contact the electrode connection layer.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various embodiments of the present disclosure;

FIG. 2 illustrates another exemplary display panel according to various embodiments of the present disclosure;

FIG. 3 illustrates another exemplary display panel according to various embodiments of the present disclosure;

FIG. 4 illustrates another exemplary display panel according to various embodiments of the present disclosure;

FIG. 5 illustrates another exemplary display panel according to various embodiments of the present disclosure;

FIG. 6 illustrates another exemplary display panel according to various embodiments of the present disclosure;

FIG. 7 illustrates another exemplary display panel according to various embodiments of the present disclosure;

FIG. 8 illustrates another exemplary display panel according to various embodiments of the present disclosure;

FIG. 9 illustrates an exemplary light-emitting function layer according to various embodiments of the present disclosure;

FIG. 10 illustrates another exemplary light-emitting function layer according to various embodiments of the present disclosure;

FIG. 11 ILLUSTRATES AN EXEMPLARY OLED STRUCTURE ACCORDING TO VARIOUS

embodiments of the present disclosure;

FIG. 12 illustrates another exemplary OLED structure according to various embodiments of the present disclosure;

FIG. 13 illustrates another exemplary display panel according to various embodiments of the present disclosure;

FIG. 14 illustrates another exemplary display panel according to various embodiments of the present disclosure;

FIG. 15 illustrates another exemplary display panel according to various embodiments of the present disclosure;

FIG. 16 illustrates another exemplary display panel according to various embodiments of the present disclosure;

FIG. 17 illustrates another exemplary display panel according to various embodiments of the present disclosure;

FIG. 18 illustrates an exemplary optical path according to various embodiments of the present disclosure;

FIG. 19 illustrates another exemplary display panel according to various embodiments of the present disclosure;

FIG. 20 illustrates another exemplary optical path according to various embodiments of the present disclosure;

FIG. 21 illustrates another exemplary display panel according to various embodiments of the present disclosure; and

FIG. 22 illustrate an exemplary electronic device according to various embodiments of the present disclosure.

### DETAILED DESCRIPTION

The following will be combined with the drawings in the embodiments of the present disclosure to clearly and completely describe the technical solutions in the embodiments of the present disclosure. Obviously, the described embodiments are only part of the embodiments of the present disclosure, not all of the embodiments. Based on the embodiments in the present disclosure, all other embodiments obtained by ordinary technicians in the field without creative work are within the scope of protection of the present disclosure.

As described in the background technology, organic light-emitting diodes are active light-emitting devices. Compared with the traditional liquid crystal display mode, OLED display technology does not require a backlight and has the characteristics of self-luminescence. OLED uses a thinner organic material layer to form a light-emitting device. When a current passes through, the organic material will emit light. OLED display panels have the advantages of saving electricity and being lighter and thinner. OLED display panels can withstand a wider range of temperature changes than LCD display panels and have a larger viewing angle. OLED display panels are one of the most concerned technologies in flat panel display technology. Although OLED display panels have many advantages, the packaging reliability of OLED display panels today has some issues and needs to be further improved.

Specifically, in the formation process of OLED display panels, the preparation of RGB light-emitting functional layers is generally made by FMM evaporation technology. However, due to the limitation of the FMM process, the FMM process for forming the RGB light-emitting functional layer needs a large shadow, which is difficult to use for ultra-high pixel density (pixel per inch, PPI) products. At the same time, the evaporation of large-size panels is limited by the uncontrollable factors of the mask strip (sheet) drooping deformation, so the RGB light-emitting functional layer cannot be evaporated using FMM. With the development of display technology, high-end mobile displays require larger sizes, higher resolutions, higher color gamut, and lower power consumption. Therefore, evaporating the RGB light-emitting functional layer without FMM becomes an important development direction. However, the display panel formed by the FMM-free evaporation process has a poor packaging structure in the display panel due to the particularity of the prepared pixel definition structure, which has a certain risk of water vapor erosion, reducing the packaging reliability of the display panel.

The present disclosure provides a display panel and an electronic device, which may effectively solve the existing technical problems, reduce the risk of the display panel being susceptible to water vapor erosion, and improve the packaging reliability of the display panel.

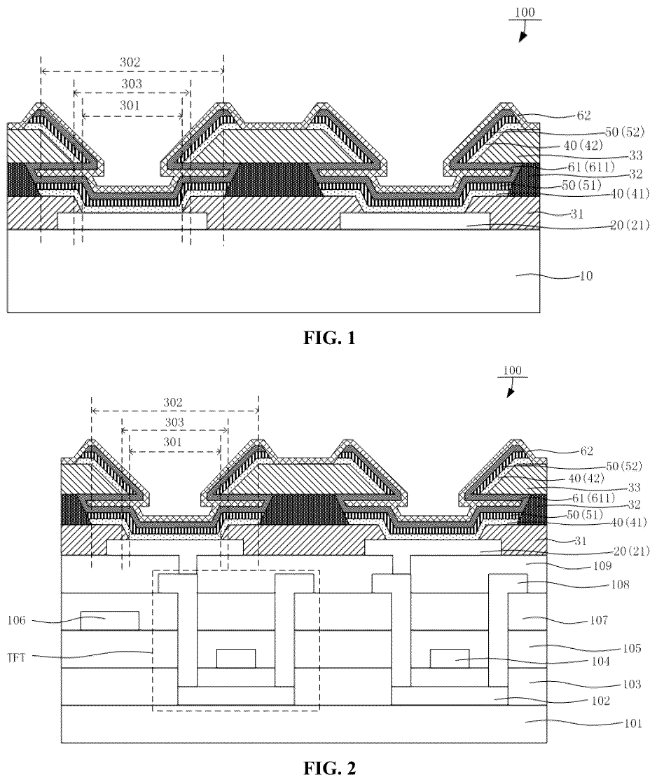

To achieve the above-mentioned purpose, the technical solution provided by the embodiments of the present disclosure is as follows, and the technical solution provided by the embodiments of the present disclosure are described in detail in combination with FIGS. 1-22.

FIG. 1 illustrates a schematic diagram of the structure of an exemplary display panel according to various disclosed embodiments of the present disclosure. As shown in FIG. 1, the display panel 100 provided by one embodiment of the present disclosure may include a substrate 10 and an anode layer 20. The anode layer 20 may be located on the substrate 10, and the anode layer 20 may include a plurality of anode blocks 21. The display panel 100 may also include a first pixel definition layer 31. The first pixel definition layer 31 may be located on the side of the anode layer 20 away from the substrate 10, and the pixel definition layer 31 may include a first pixel opening 301 corresponding to the anode block 21. Further, the display panel may include an electrode connection layer 32. The electrode connection layer 32 may be located on the side of the pixel definition layer 31 away from the substrate 10, and the electrode connection layer 32 may include a second pixel opening 302 corresponding to the first pixel opening 301. Further, the display panel 100 may include a second pixel definition layer 33. The second pixel definition layer 33 may be located on the side of the electrode connection layer 32 away from the substrate 10, and the second pixel definition layer 33 may include a third pixel opening 303 corresponding to the second pixel opening 302. Further, the display panel 100 may include a light-emitting functional layer 40. The light-emitting functional layer 40 may include a plurality of first portions 41 and a plurality of second portions 42. The first portion 41 may be at least located in the first pixel opening 301, and the second portion 42 may at least cover the sidewall of the third pixel opening 303. Further, the display panel 100 may include a cathode layer 50. The cathode layer 50 may include a first cathode portion 51 and a second cathode portion 52. The first cathode portion 51 may cover the first portion 41 and may extend to contact the electrode connection layer 32, so that all the first portions 41 in the display panel 100 may be connected through the electrode connection layer 32, which may be equivalent to forming the entire cathode in the display panel 100. Further, the display panel 100 may include a first inorganic film 61. The first inorganic film 61 may be located on the side of the cathode layer 50 away from the substrate 10. Further, the display panel may include a second inorganic film 62. The second inorganic film 62 may be located on the side of the first inorganic film 61 away from the substrate 10, and the second inorganic film 62 may cover the first inorganic film 61.

As described above, the technical solution provided by the embodiments of the present disclosure, the display panel 100 may include a superposition structure of the first pixel definition layer 31, the electrode connection layer 32 and the second pixel definition layer 33, and the first pixel opening 301, the second pixel opening 302 and the third pixel opening 303 based on the superposition structure, the light-emitting functional layer 40 may be formed without an FMM, so as not to be affected by the related problems caused by the FMM process. That is, before forming the light-emitting functional layer 40 of the display panel 100, the superimposed structure of the first pixel definition layer 31, the electrode connection layer 32 and the second pixel definition layer 33 may be formed, and then the light-emitting functional layer 40 and the cathode layer 50 may be formed based on the open mask process and a patterning process. The light-emitting functional layer 40 and the cathode layer 50 formed by such a process may include not only the first portion 41 located at least at the first pixel opening 301, but also the second portion 42 located at least at the inner wall of the second pixel definition layer 33 at the pixel opening (that is, the sidewall of the third pixel opening 303). It can be seen that the present disclosure may not need to adopt the FMM process to form the light-emitting functional layer 40. The process of forming the light-emitting functional layer 40 using the FMM process is the same as the prior art, so the present disclosure will not make redundant descriptions.

Further, the display panel 100 provided in the embodiments of the present disclosure may also include the first inorganic layer 61 formed after the cathode layer 50. Because the display panel 100 may include the superimposed structure of the first pixel definition layer 31, the electrode connection layer 32, and the second pixel definition layer 33, and a corner structure may be inevitably formed between two adjacent structural layers in the superimposed structure, the first inorganic film 61 may be prone to cracks and other problems at these corner structures, so that a water vapor erosion channel may occur at the first inorganic film 61. The display panel 100 provided in the embodiments of the present disclosure may also include the second inorganic film 62 covering the first inorganic film 61. Therefore, when a water vapor erosion channel occurs at the first inorganic film 61, it may be covered and blocked by the second inorganic film 62, thereby reducing the risk of the display panel 100 being susceptible to the water vapor erosion and improving the packaging reliability of the display panel 100.

In some embodiments, during the formation of the display panel 100, the patterning etching process of the light-emitting functional layer 40 and the cathode layer 50 may be performed after the formation of the first inorganic film 61 is completed. Because the light-emitting functional layer 40 may need to be etched and divided at the boundary between adjacent pixel units to achieve single-pixel packaging, the first inorganic film 61 may also etched and divided into a plurality of inorganic film blocks 611. Continuing to refer to FIG. 1, the first inorganic film 61 provided in the embodiments of the present disclosure may include a plurality of inorganic film blocks 611, and the inorganic film blocks 611 may cover the first cathode portion 51 and extend to cover the second cathode portion 52 away from the second portion 42. Among them, the inorganic film block 611 may not only be prone to cracks and other problems at the corner structure of the superimposed structure of the first pixel definition layer 31, the electrode connection layer 32 and the second pixel definition layer 33, so that a water vapor erosion channel may occur at the crack; the inorganic film block 611 may be etched and divided, and a water vapor erosion channel may also be formed at the second portion 42 and the second cathode portion 52. Therefore, the second inorganic film 62 may be used to cover and block the water vapor erosion channel at the inorganic film block 611, thereby reducing the risk of the display panel 100 being susceptible to water vapor erosion and improving the packaging reliability of the display panel 100. In some other embodiments, the first inorganic film 61 may also be formed after the patterned etching process of the light-emitting functional layer 40 and the cathode layer 50 is completed. The first inorganic film 61 may also be a whole-surface film structure, which is not specifically limited in the present disclosure.

The substrate 10 provided in the embodiments of the present disclosure may be composed of structural layers such as multiple metal layers and multiple insulation layers, and these structural layers may be formed as circuits such as pixel circuits and scanning drive circuits in the substrate 10. Among them, the scanning drive circuit may be electrically connected to the pixel circuit, and the scanning drive circuit may be configured to provide a corresponding scanning control signal for the pixel circuit; and the pixel circuit may be electrically connected to the anode block 21, and the pixel circuit may be configured to provide a corresponding driving signal for the OLED composed of the anode block 21, the first portion 41 and the first cathode portion 51. The scanning drive circuit and the pixel circuit may be both composed of components such as transistors and capacitors, which may be the same as the prior art, so no redundant description is made.

FIG. 2 illustrates a schematic diagram of the structure of another exemplary display panel 100 provided in one embodiment of the present disclosure. As shown in FIG. 2, the display panel 100 may include a substrate 10. The substrate 10 may include a base substrate 101 and a semiconductor layer 102 located on the base substrate 101. The semiconductor layer 102 may include an active region for forming a transistor TFT; a gate insulation layer 103 located on a side of the semiconductor layer 102 away from the base substrate 101; and a gate metal layer 104 located on a side of the gate insulation layer 103 away from the base substrate 101. The gate metal layer 104 may include a gate electrode for forming the transistor TFT. Further, the substrate 10 may include a capacitor insulation layer 105 located on a side of the gate metal layer 104 away from the base substrate 101; and a capacitor metal layer 106 located on a side of the capacitor insulation layer 105 away from the base substrate 101. The capacitor metal layer 106 may include a plate for forming a capacitor in the circuit, and the other plate for forming the capacitor may be located on the gate metal layer 104, or the other plate for forming the capacitor may be located on the gate metal layer 104. Further, the substrate 10 may include a source-drain metal layer 108; an interlayer insulation layer 107 located on the side of the capacitor metal layer 106 away from the base substrate 101; and the source-drain metal layer 108 located on the side of interlayer insulation layer 107 away from substrate 101. The source-drain metal layer 108 may include the source and drain for forming the transistor TFT, and the source and drain may contact the active area through respective vias. Further, the substate 10 may include a planarization layer 109 located on the side of the source-drain metal layer 108 away from the base substrate 101. The display panel may also include an anode layer 20 located on the side of the planarization layer 109 away from the base substrate 101. The anode layer 20 may include multiple anode blocks 21, and the anode blocks 21 and the source or drain of the corresponding transistor TFT in the pixel circuit may be electrically connected through vias. Further, the display panel 100 may include a first pixel definition layer 31 located on the side of the anode layer 20 away from the base substrate 101. The first pixel definition layer 31 may include multiple first pixel openings 301. The first pixel openings 301 may expose the anode blocks 21.

In the display panel 100 shown in FIG. 2, the transistor TFT in the substrate 10 may be a top-gate transistor, that is, the gate of the transistor TFT may be located above the active layer. In some other embodiments, the transistor TFT in the substrate 10 provided in the embodiment of the present disclosure may also be a bottom-gate transistor, that is, the gate of the transistor TFT may be located below the active layer.

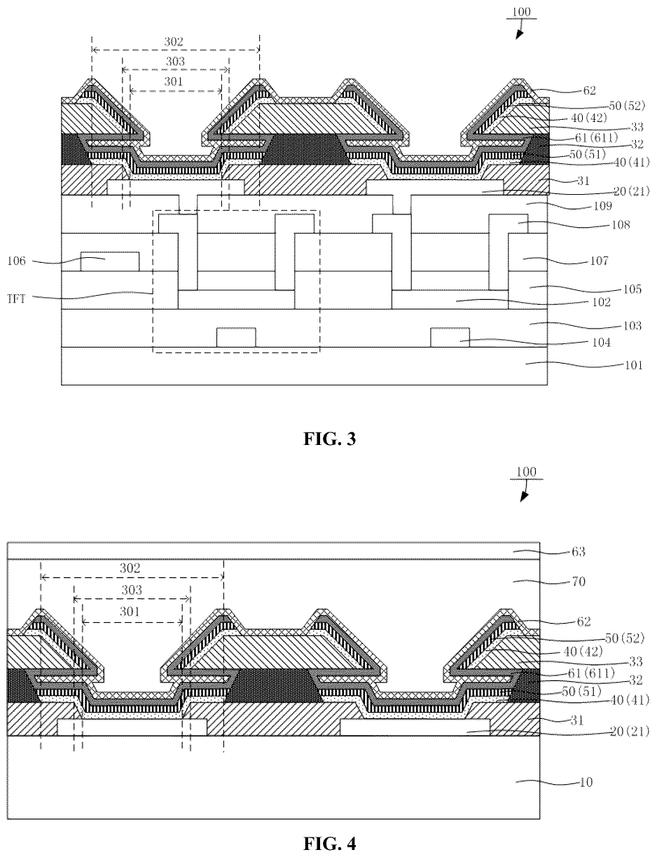

FIG. 3 illustrates a schematic diagram of the structure of another exemplary display panel 100 provided in one embodiment of the present disclosure. As shown in FIG. 3, the display panel 100 may include a substrate 10. The substate 10 may include a base substrate 101 and a gate metal layer 104 located on the substrate 101. The gate metal layer 104 may include a gate electrode for forming a transistor TFT. The substate 10 may also include a gate insulation layer 103 located on a side of the gate metal layer 104 away from the base substrate 101; and a semiconductor layer 102 located on a side of the gate insulation layer 103 away from the base substrate 101. The semiconductor layer 102 may include an active region for forming the transistor TFT. Further, the substrate 10 may include a capacitor insulation layer 105 located on a side of the semiconductor layer 102 away from the base substrate 101; and a capacitor metal layer 106 located on a side of the capacitor insulation layer 105 away from the substrate 101. The capacitor metal layer 106 may include a plate for forming a capacitor in the circuit, and the other plate for forming the capacitor may be located on the gate metal layer 104, or the other plate for forming the capacitor may be located on at the source-drain metal layer 108. Further, the substate 10 may include an interlayer insulation layer 107 located on the side of the capacitor metal layer 106 away from the base substrate 101; and the source-drain metal layer 108 located on the side of the interlayer insulation layer 107 away from the base substrate 101. The source-drain metal layer 108 may include a source and a drain for forming a transistor TFT, and the source and the drain may be in contact with the active area through respective vias. Further, the substrate 10 may include a planarization layer 109 located on the side of the source-drain metal layer 108 away from the base substrate 101. The display panel may also include an anode layer 20 located on the side of the planarization layer 109 away from the base substrate 101. The anode layer 20 may include a plurality of anode blocks 21, and the anode blocks 21 may be electrically connected to the source or drain of the corresponding transistor TFT in the pixel circuit through vias. Further, the display panel 100 may include a first pixel definition layer 31 located on the side of the anode layer 20 away from the substrate 101. The first pixel definition layer 31 may include a plurality of first pixel openings 301, and the first pixel openings 301 may expose the anode blocks 21.

FIG. 4 illustrates a schematic diagram of the structure of another exemplary display panel 100 provided in one embodiment of the present disclosure. As shown in FIG. 4, the display panel 100 provided in one embodiment of the present disclosure may further include an organic film 70 located on the side of the second inorganic film 62 away from the substrate 10, and a third inorganic film 63 located on the side of the organic film 70 away from the substrate. An encapsulation structure provided in one embodiment of the present disclosure may include the first inorganic film 61, the second inorganic film 62, the organic film 70 and the third inorganic film 63 stacked in sequence. The inorganic film may effectively prevent water vapor and the like from invading the interior of the display panel 100. Inserting the organic film 70 between the inorganic layers may help to stabilize the uneven properties of the inorganic layers and improve the stress and flexibility of the encapsulation structure. Thus, the encapsulation reliability of the display panel 100 may be further improved by cooperating between the first inorganic film 61, the second inorganic film 62, the organic film 70 and the third inorganic film 63. In one embodiment, at least one inorganic film (such as at least one of the first inorganic film 61, the second inorganic film 62 and the third inorganic film 63) in the display panel 100 may include a SiOx layer, a SiNx layer, or a SiOx/SiNx laminated layer. In addition, the embodiment of the present disclosure does not specifically limit the thickness of the inorganic layer, and the thickness may need to be adaptively adjusted according to the actual application to cooperate with other layers to optimize the light-emitting effect of the OLED.

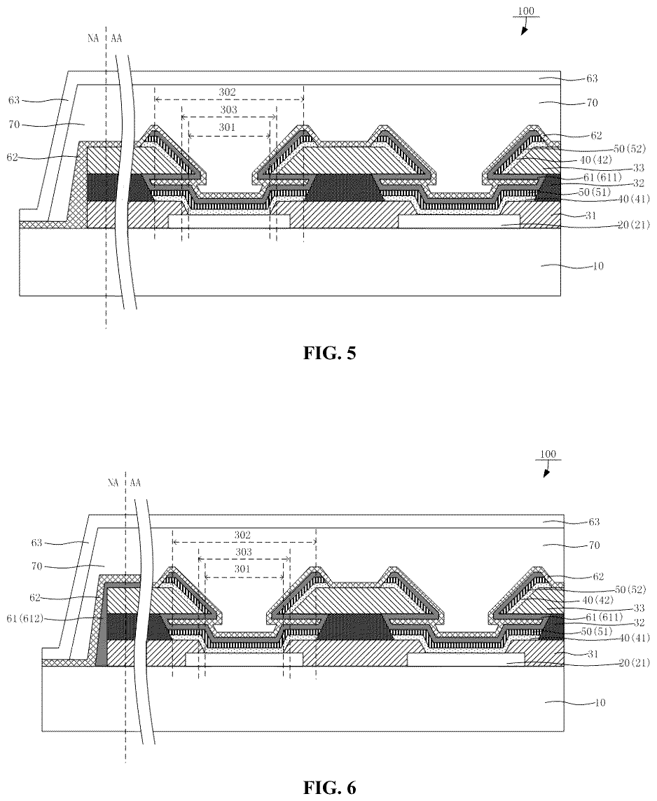

In addition to adding the organic film 70 and the third inorganic film 63 on the second inorganic film 62 to improve the packaging reliability of the display panel 100, the present disclosure may also optimize the coverage of the second inorganic film 62 to improve the packaging reliability of the display panel 100. In some embodiments, the display panel 100 may be a frameless display panel 100, which may only include a display area AA, the scanning drive circuit and the pixel circuit may both be arranged in the display area AA, and the second inorganic film 62 may cover the display area AA. In other embodiments, the display panel 100 may also be a narrow frame display panel 100 including a display area AA and a frame area NA, the scanning drive circuit may be arranged in the frame area NA, and the pixel circuit may be arranged in the display area AA. The second inorganic film 62 may not only cover the display area AA, but also extend to cover at least a portion of the frame area NA, so as to further improve the packaging reliability of the display panel 100. Specifically, referring to FIG. 5, which is a structural schematic diagram of another exemplary display panel 100 provided in one embodiment of the present disclosure, the display panel 100 may include a display area AA and a frame area NA surrounding at least a portion of the display area AA, and the second inorganic film 62 may cover the display area AA and extend to cover at least a portion of the frame area NA. Among them, the second inorganic layer 62 may not only block the water vapor erosion at the display area AA, but also block the water vapor erosion of the frame area NA, further improving the packaging reliability of the display panel 100. Continuing to refer to FIG. 5, the first inorganic film 61 provided in one embodiment of the present disclosure may only include an inorganic film block 611 located in the display area AA and corresponding to the first portion 41, and the first inorganic film 61 may not be formed in the portion of the frame area NA, or may be etched and removed after preparation.

FIG. 6 illustrates a structural schematic diagram of another exemplary display panel 100 provided in one embodiment of the present disclosure. As shown in FIG. 6, the first inorganic film 61 may include not only the inorganic film block 611 located in the display area AA, but also an inorganic film block 612 covering at least a portion of the frame area NA, and the first inorganic film 61 and the second inorganic film 62 may be used to jointly block the water vapor erosion in the frame area NA, thereby improving the packaging reliability of the display panel 100.

Continuing to refer to FIG. 5 and FIG. 6, the packaging structure of the display panel 100 provided in one embodiment of the present disclosure may include the organic film 70 and the third inorganic film 63, and the organic film 70, and the third inorganic film 63 may also cover the display area AA, and extend to cover at least a portion of the frame area NA. Further, the first inorganic film 61 and the third inorganic film 63 may contact each other at the frame area NA to form a type of sealed cavity, and the organic film 70 may be located in the sealed cavity to avoid the formation of a water vapor erosion channel at the edge of the organic film 70, thereby ensuring the high packaging reliability of the display panel 100.

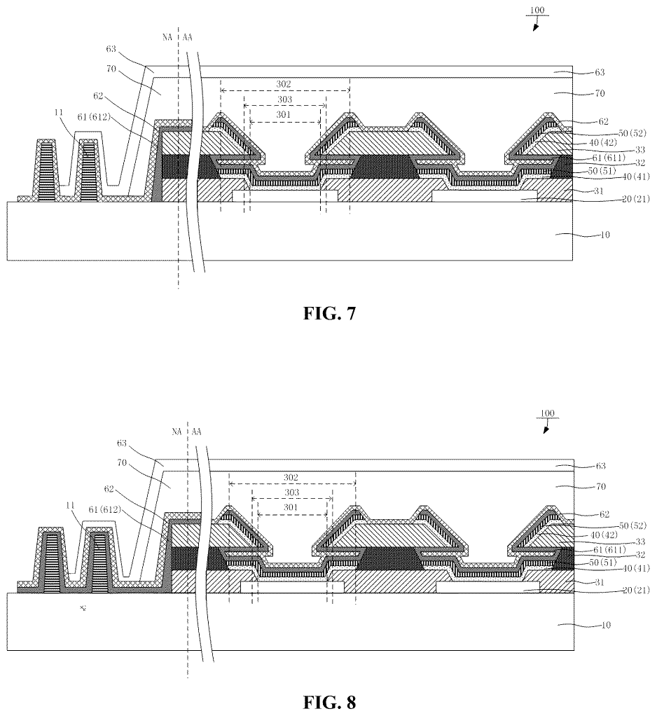

In some embodiments, the frame area NA of the display panel 100 may be provided with at least one retaining wall 11 arranged along the direction surrounding the display area AA, and the at least one inorganic film may also extend to the retaining wall 11 to improve the packaging reliability. FIG. 7 illustrates a structural schematic diagram of another exemplary display panel 100 according to various disclosed embodiments of the present disclosure. As shown in FIG. 7, the frame area NA provided in one embodiment of the present disclosure may include at least one retaining wall 11 arranged along the direction surrounding the display area AA, and the retaining wall 11 may be arranged on the side of the substrate 10 having the OLED. The retaining wall 11 may be formed by multiplexing at least two structures of the planarization layer 109, the first pixel definition layer 31 and the second pixel definition layer 32 in the display panel 100. In another embodiment, the retaining wall 11 may also be formed from a single material. Among them, the second inorganic film 62 provided in one embodiment of the present disclosure may cover the display area AA and extend to the outside of the at least one retaining wall 11. As shown in FIG. 7, the second inorganic film 62 may extend to the outside of all the retaining walls 11 (for example, the second inorganic film 62 may extend to the clearance area outside all the retaining walls 11). Therefore, not only may the second inorganic film 62 block water vapor erosion, but the retaining walls 11 may also block water vapor erosion, thereby further improving the packaging reliability of the display panel 100.

It should be noted that when the display panel 100 provided in one embodiment of the present disclosure may include a retaining wall 11, the packaging structure may not be limited to the structure shown in FIG. 7, which is only one of all packaging structures applicable to the present disclosure. In some other embodiments, the first inorganic film 61 may include an inorganic layer portion 612 covering at least a portion of the frame area NA, and the first inorganic film 61 may also extend to cover at least one retaining wall 11, such as extending to cover one retaining wall 11, or extending to cover more or even all retaining walls 11 (specifically, the first inorganic film 61 may extend to cover all retaining walls 11 as shown in FIG. 8), and the present disclosure does not make specific restrictions on this. Similarly, the third inorganic film 63 provided in one embodiment of the present disclosure may also extend to cover at least one retaining wall 11, for example, extending to cover one retaining wall 11, or extending to cover more or even all retaining walls 11, and the present disclosure does not make specific restrictions on this.

In some embodiments, the electrode connection layer 32 may expose the surface of the first pixel definition layer 31 on the side away from the substrate 10; and the second pixel definition layer 33 may face the bottom surface of the substrate 10 and extend to the outside of the surface of the electrode connection layer 32 on the side away from the substrate 10, thereby forming an undercut structure between the second pixel definition layer 33 and the electrode connection layer 32, which may be not only convenient for single pixel packaging, but also conducive to color gamut improvement. As shown in FIGS. 1-8, the second pixel definition layer 33 provided in one embodiment of the present disclosure may face the bottom surface of the substrate 10 and extend to the outside of the surface of the electrode connection layer 32 on the side away from the substrate 10, so that the orthographic projection of the second pixel opening 302 on the substrate 10 may completely cover the orthographic projection of the third pixel opening 303 on the substrate 10, thereby forming an undercut structure between the second pixel definition layer 33 and the electrode connection layer 32, which may be conducive to single pixel packaging and color gamut improvement.

In addition, the electrode connection layer 32 provided in one embodiment of the present disclosure may expose the surface of the first pixel definition layer 31 away from the substrate 10, so that the orthographic projection of the second pixel opening 302 on the substrate 10 may completely cover the orthographic projection of the first pixel opening 301 on the substrate 10. While the light-emitting functional layer 40 may be formed by the non-FMM process, the first portion 41 may extend to the sidewall of the second pixel opening 302 (e.g., the inner wall of the electrode connection layer 32 at the second pixel opening 302), which may be equivalent to increasing the light-emitting area of the first portion 41, thereby improving the light-emitting efficiency and light-emitting area of the OLED.

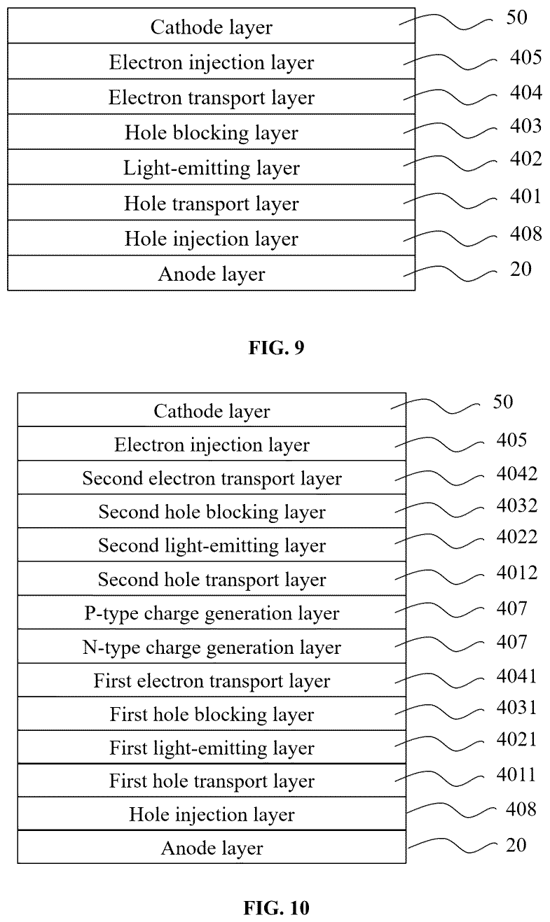

In some embodiments, the light-emitting functional layer 40 may only include a light-emitting layer. In such a case, the light-emitting efficiency of the OLED may be improved by increasing the light-emitting area of the first portion 41 as described above. In addition, in addition to increasing the light-emitting area of the first portion 41, the embodiment of the present disclosure may also optimize the design of the superimposed structure of the light-emitting functional layer 40 itself to achieve the purpose of improving the light-emitting efficiency of the OLED. Specific reference is made to FIG. 9, which is a schematic diagram of the structure of an exemplary light-emitting functional layer according to various disclosed embodiments. The light-emitting functional layer 40 may include a hole transport layer 401, a light-emitting layer 402, a hole blocking layer 403 and an electron transport layer 404, which may be located on the anode layer 20 and stacked in sequence. The light-emitting functional layer 40 may further include a hole injection layer 408 located between the anode layer 20 and the hole transport layer 401, and an electron injection layer 405 located on the side of the electron transport layer 404 away from the anode layer 20. The cathode layer 50 may be located on the side of the electron injection layer 405 away from the anode layer 20, thereby optimizing the structure of the light-emitting functional layer 40 to achieve the purpose of improving the light-emitting efficiency of the OLED.

FIG. 10 illustrates a schematic diagram of the structure of another exemplary light-emitting functional layer provided in one embodiment of the present disclosure. As shown in FIG. 10, the light-emitting functional layer 40 may include a first hole transport layer 4011, a first light-emitting layer 4021, a first hole blocking layer 4031, a first electron transport layer 4041, an N-type charge generation layer 406, a P-type charge generation layer 407, a second hole transport layer 4012, a second light-emitting layer 4022, a second hole blocking layer 4032 and a second electron transport layer 4042, which may be located on the anode layer 20 and stacked in sequence. The light-emitting functional layer 40 may further include a hole injection layer 408 located between the anode layer 20 and the hole transport layer 401, and an electron injection layer 405 located on the side of the second electron transport layer 4042 away from the anode layer 20. The cathode layer 50 may be located on the side of the electron injection layer 405 away from the anode layer 20. It can be understood that the light-emitting functional layer 40 provided in one embodiment of the present application may include two light-emitting layers and a charge generation layer located between the light-emitting layers. The two independent light-emitting layers may be connected together through the intermediate charge generation layer. Under the action of the external electric field, the charge generation layer may generate holes and electrons, which are respectively injected into the hole transport layer and the electron transport layer of the two adjacent light-emitting layers, and may be respectively combined with the electrons from the cathode layer 50 and the holes from the anode layer 20 in the light-emitting layer, so that the light-emitting layer may emit light. Among them, the N-type charge generation layer 406 may be used to inject electrons into the light-emitting layer connected thereto, and the P-type charge generation layer 407 may be used to inject holes into the light-emitting layer connected thereto, thereby ensuring that the charges may be effectively distributed to the light-emitting layer while improving the current efficiency of each light-emitting layer, thereby achieving the purpose of improving the light-emitting efficiency of the OLED.

It should be noted that the light-emitting functional layer 40 provided in the embodiments of the present disclosure may be composed of a light-emitting layer 402 as shown in FIG. 9, or may be composed of two light-emitting layers as shown in FIG. 10, and this disclosure does not make specific restrictions on this. In some other embodiments, the light-emitting functional layer 40 provided in the embodiment of the present disclosure may also be composed of more light-emitting layers stacked, and may also include more structural layers for optimizing light emission, which needs to be specifically designed according to the actual application.

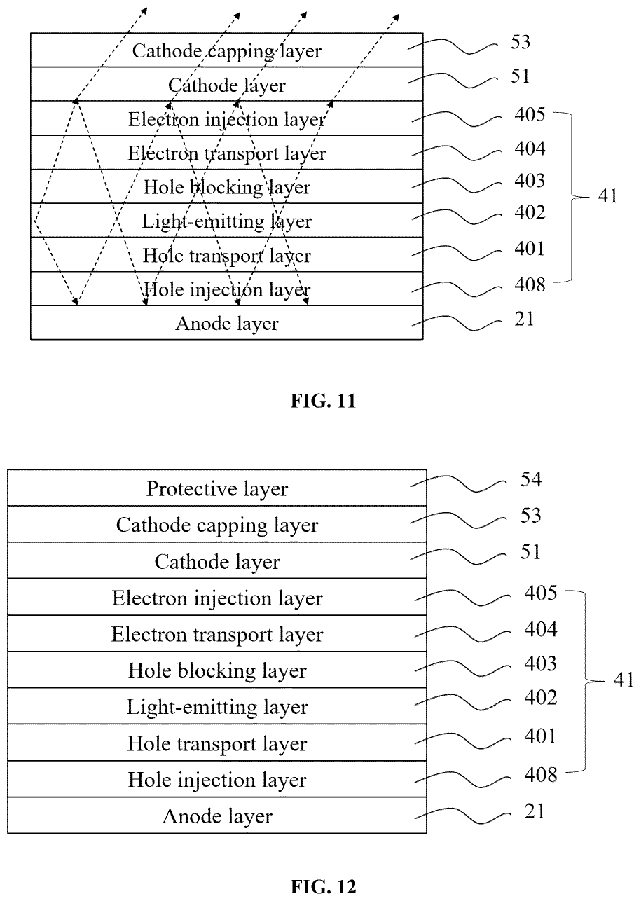

FIG. 11 illustrates a structural schematic diagram of an exemplary OLED provided in one embodiment of the present disclosure. As shown in FIG. 11, the OLED may include an anode block 21, a first portion 41 and a first cathode portion 51. The first portion 41 shown in FIG. 11 is taken as an example of the light-emitting functional layer 40 shown in FIG. 9. Further, the OLED provided in the embodiment of the present disclosure may also include a cathode capping layer 53 covering the first cathode portion 51, and the cathode capping layer 53 may be located between the first cathode portion 51 and the inorganic module 611 and may be configured to form an optical microcavity, thereby improving the light extraction and color purity of the OLED through the microcavity effect. As shown in the light indicated by the dotted arrow in FIG. 11, the setting of the cathode capping layer 53 may make the light emitted from the light-emitting layer 42 reflect multiple times between the first cathode portion 51 and the anode block 21, thereby generating a strong interference effect. In one embodiment, the cathode covering layer 53 may be made of a high refractive index material, and the present disclosure does not make any specific restrictions on this.

FIG. 12 illustrates a schematic diagram of the structure of another exemplary OLED provided in one embodiment of the present disclosure. As shown in FIG. 12, the OLED provided in the embodiment of the present disclosure may also include a protective layer 54 located on the cathode covering layer 53. The protective layer 54 may be located between the cathode covering layer 53 and the inorganic layer block 611. The protective layer 54 may at least play the role of protecting the cathode covering layer 53. In one embodiment, the protective layer 54 may be made of lithium fluoride (LiF).

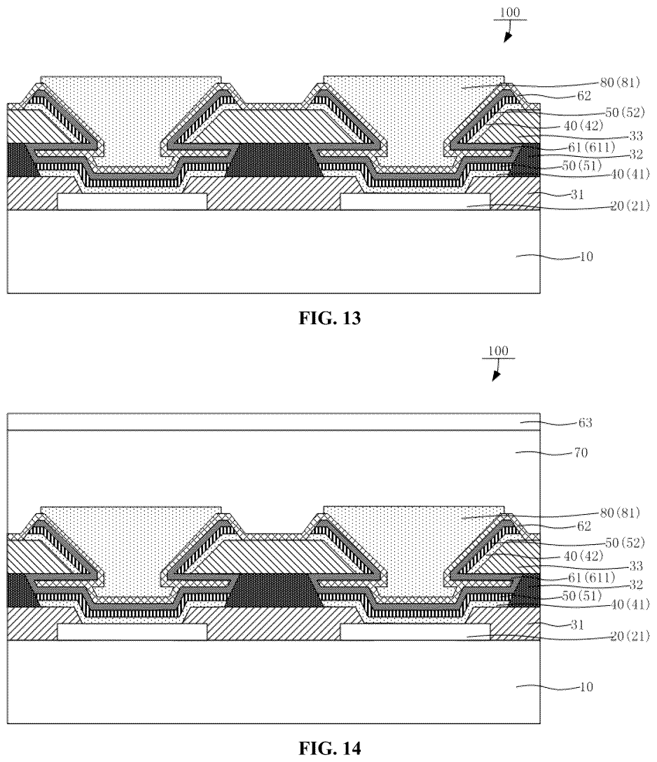

In some embodiments, the display panel 100 may be formed as a CFOT (Color Filter On TFE) type display panel, that is, a color resistor may be formed in the packaging structure of the display panel 100. Specific reference may be made to FIG. 13, which is a structural schematic diagram of another exemplary display panel 100 provided in one embodiment of the present disclosure. As shown in FIG. 13, the display panel 100 may further include a color resist layer 80. The color resist layer 80 may be located on the side of the second inorganic layer 62 away from the substrate 10. The color resist layer 80 may include a plurality of color resist portions 81. The color resist portion 81 may be arranged corresponding to the first portion 41. The color resist portion 81 may be used to filter out the color light corresponding to the first portion 41. For example, the first portion 41 provided in one embodiment of the present disclosure may include a red light portion, a green light portion, and a blue light portion. The color resist portion 81 corresponding to the red light portion may filter out the remaining color light through red light, the color resist portion 81 corresponding to the green light portion may filter out the remaining color light through green light, and the color resist portion 81 corresponding to the blue light portion may filter out the remaining color light through blue light. Such a configuration may not only make it unnecessary to set a polarizer for the display panel 100, but also improve the display effect of the display panel 100 by filtering out stray light other than the light output of the first portion 41.

When the display panel 100 provided in one embodiment of the present disclosure is also encapsulated by the organic film 70 and the third inorganic film 63, the color resist layer 80 may be formed before the organic film 70. Referring to FIG. 14, which is a schematic structural diagram of another exemplary display panel 100 provided in one embodiment of the present disclosure, the display panel 100 may further include an organic film 70. The organic film 70 may be located on the side of the second inorganic film 62 away from the substrate 10. The display panel 100 may also include a third inorganic film 63. The third inorganic film 63 may be located on the side of the organic film 70 away from the substrate 10. The color resist portion 81 may be located between the second inorganic film 62 and the organic film 70. The technical solution provided in the embodiment of the present disclosure may integrate the color resist layer 80 into the encapsulation structure, and multiplex the organic film 70 and the third inorganic film 63 as a protective layer to protect the color resist layer 80, so that there may be no need to form a protective film layer separately, which may reduce the fabrication steps of the display panel 100 and reduce the production cost of the display panel 100. Furthermore, the second pixel definition layer 33 provided in one embodiment of the present disclosure may be a black matrix, which may be used to block ambient light, thereby improving the display effect of the display panel 100. Further, the embodiment of the present disclosure may multiplex the second pixel definition layer 33 as a black matrix, so that there may be no need to form a black matrix structure separately, further reducing the fabrication steps of the display panel 100 and reducing the production cost of the display panel 100.

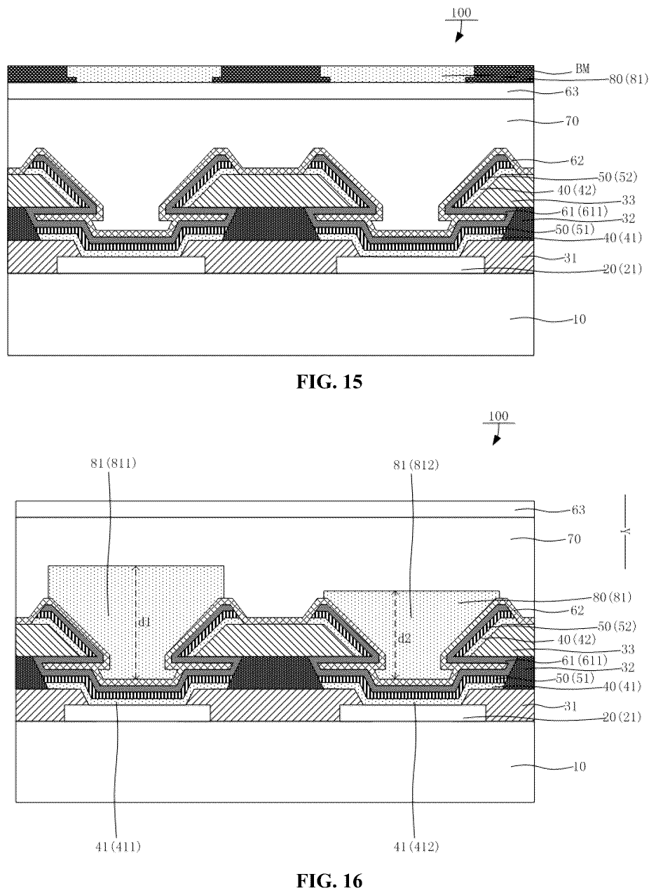

Alternatively, when the display panel 100 provided in the embodiment of the present disclosure is also encapsulated by the organic film 70 and the third inorganic film 63, the color resist layer 80 may also be formed after the third inorganic film 63. Referring to FIG. 15, which is a schematic diagram of the structure of another exemplary display panel 100 provided in one embodiment of the present disclosure, the display panel 100 may further include an organic film 70. The organic film 70 may be located on the side of the second inorganic film 62 away from the substrate 10. The display panel may also include a third inorganic film 63. The third inorganic film 73 may be located on the side of the organic film 70 away from the substrate 10. The color resist portion 81 may be located on the side of the third inorganic film 63 away from the substrate 10. The display panel 100 may further include a black matrix BM located on the side of the third inorganic film 63 away from the substrate 10, and the black matrix BM may surround the color resistance portion 81. The arrangement of the color resist portion 81 may not only improve the display effect of the display panel 100, but also omit the polarizer in the display panel 100; and the display effect of the display panel 100 may be further improved by shielding the ambient light through the black matrix BM.

It should be noted that the color resist portion 81 provided in the embodiment of the present disclosure may be disposed between the second inorganic film 62 and the organic film 70 as shown in FIG. 12, and the color resist portion 81 may also be disposed on the third inorganic film 63 as shown in FIG. 13, and the disposition position of the color resist portion 81 may be selected according to the actual application, thereby expanding the applicable types of the display panel 100. In addition, the color resist portion 81 provided in the embodiment of the present disclosure may be set with different thicknesses according to the light emission wavelength of the first portion 41, thereby balancing the light emission efficiency of pixels of different color lights and improving the light emission uniformity of the display panel 100.

FIG. 16 illustrates a structural schematic diagram of another exemplary display panel 100 provided in one embodiment of the present disclosure. As shown in FIG. 16, the display panel 100 provided in the embodiment of the present disclosure may include a first portion 41 of at least two light-emitting colors, that is, the first portion 41 provided in the embodiment of the present disclosure may at least include a first color light portion 411 and a second color light portion 412, and the wavelength of the first color light portion 411 may be greater than the wavelength of the second color light portion 412. The color resist portion 81 corresponding to the first color light portion 411 may be the first color light color resist portion 811, and the color resist portion 81 corresponding to the second color light portion 412 may be the second color light color resist portion 812. In the direction Y perpendicular to the plane where the display panel 100 is located, the thickness d1 of the first color light color resist portion 811 may be greater than the thickness d2 of the second color light color resist portion 812. Because the light effect may be positively correlated with the thickness of the color resist film, that is, the greater the thickness of the color resist film, the greater the light effect, and vice versa, the smaller the thickness of the color resist film, the smaller the light effect, so the color resist portions of different colors may be set to have different thicknesses, so as to balance the light output efficiency of the pixels corresponding to the first color light portion 411 and the pixels corresponding to the second color light portion 412, improve the light output uniformity of the display panel 100 and avoid color deviation, thereby improving the display effect of the display panel 100.

In another embodiment, the first part 41 may include a red light portion, a green light portion and a blue light portion. The color resist portion 81 corresponding to the red light portion may be a red light color resist portion, the color resist portion 81 corresponding to the green light portion may be a green light color resist portion, and the color resist portion 81 corresponding to the blue light portion may be a blue light color resist portion. Among them, the wavelength of the red light portion may be greater than that of the green light portion, and the wavelength of the green light portion may be greater than that of the blue light portion. Therefore, to balance the light output efficiency of the pixels corresponding to the red light portion, the green light portion and the blue light portion, the embodiment of the present disclosure may set the thickness of the red light color resist portion to be greater than the thickness of the blue light color resist portion and the green light color resist portion, and the thickness of the green light color resist portion may be greater than the thickness of the blue light color resist portion, or the thickness of the green light color resist portion may be set to be equal to the thickness of the blue light color resist portion, which may need to be specifically designed according to the actual application.

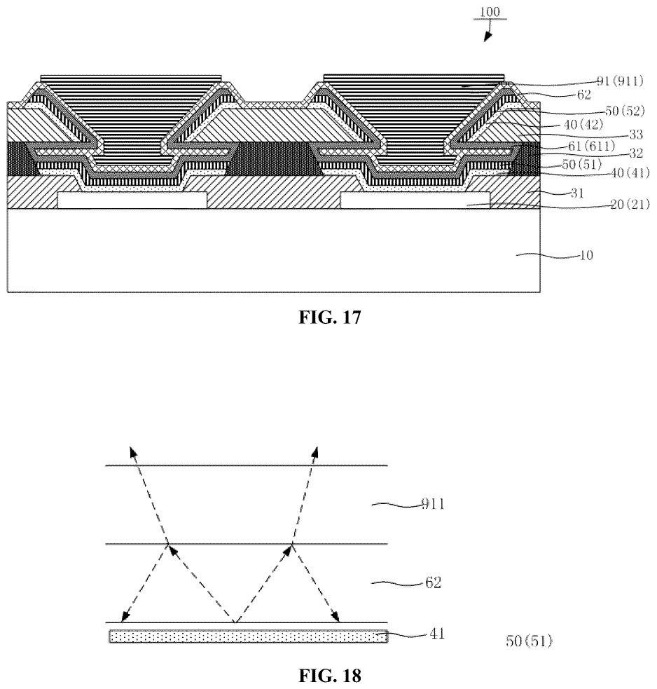

In some embodiments, the display panel 100 may also be provided with at least two refractive layers with different refractive indices corresponding to the first portion 41, so as to improve the light-emitting effect of the pixel corresponding to the first portion 41. Specifically referring to FIG. 17, which is a structural schematic diagram of another exemplary display panel 100 provided in one embodiment of the present disclosure, the display panel 100 provided in the embodiment of the present disclosure may further include a first refractive layer 91. The first refractive layer 91 may be located on the side of the second inorganic film 62 away from the substrate 10. The first refractive layer 91 may include a plurality of first refractive portions 911, and the first refractive portions 911 may be provided corresponding to the first portion 41. The refractive index of the first refractive layer 91 may be different from the refractive index of the second inorganic film 62, so that the light-emitting efficiency of the pixel at the first portion 41 may be improved by cooperating with the second inorganic film 62 and the first refractive layer 91, so as to improve the display effect of the display panel 100.

In one embodiment, the refractive index of the first refractive layer 91 may be greater than the refractive index of the second inorganic film 62. FIG. 18 illustrates an exemplary light path diagram provided by an embodiment of the present disclosure. The light path is illustrated through dotted arrows. As shown in FIG. 18, the light emitted from the first portion 41 may be incident on the interface between the second inorganic film 62 and the first refractive portion 911. Because the refractive index of the second inorganic film 62 is less than that of the first refractive portion 911, the total reflection may be reduced when the light enters the medium with a high refractive index from the medium with a low refractive index, thereby increasing the light emitted to the first refractive portion 911, improving the light extraction efficiency of the pixel there, and thus improving the display effect of the display panel 100. In some embodiments, the refractive index of the second inorganic film 62 may be the same as that of the first inorganic layer 61.

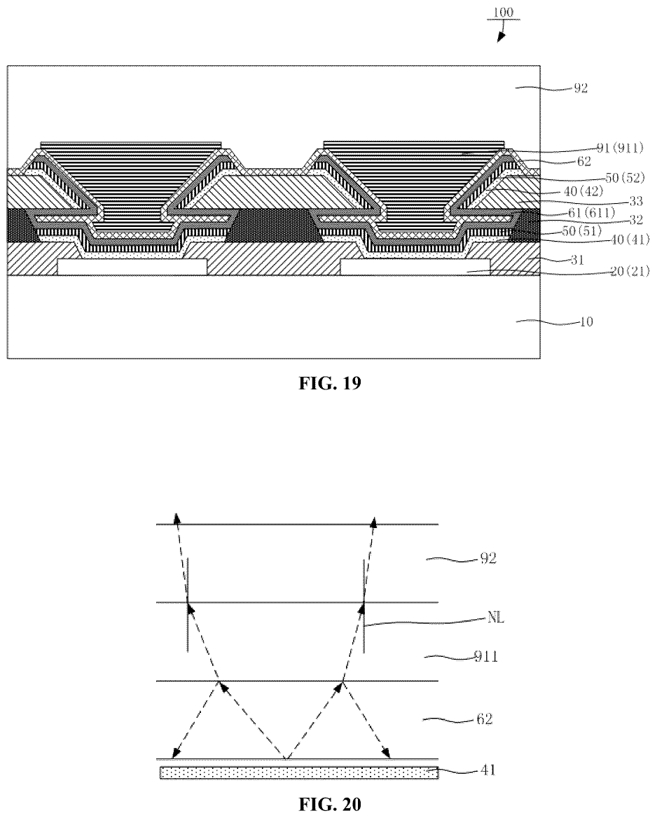

FIG. 19 illustrates a schematic diagram of the structure of another exemplary display panel 100 provided in one embodiment of the present disclosure. As shown in FIG. 19, the display panel 100 provided in the embodiment of the present disclosure may further include a second refractive layer 92. The second refractive layer 92 may be located on the side of the first refractive layer 91 away from the substrate 10. The refractive index of the second refractive layer 92 may be less than the refractive index of the first refractive layer 91, thereby through the cooperation of the second inorganic film 62, the first refractive layer 91 and the second refractive layer 92, when the light is emitted from the first portion 41, the light-emitting efficiency of the pixel there may be improved, thereby improving the display effect of the display panel 100. Specifically, as shown in FIG. 20, which is another exemplary optical path diagram provided in one embodiment of the present disclosure and the light path is illustrated through dotted arrows, the light emitted from the first portion 41 may be incident on the interface between the second inorganic film 62 and the first refractive portion 911. Because the refractive index of the second inorganic film 62 may be less than the refractive index of the first refractive portion 911, when the light enters the medium with a high refractive index from the medium with a low refractive index, the total reflection may be reduced, thereby increasing the light emitted to the first refractive portion 911. Moreover, because the light may be refracted at the interface between the second inorganic film 62 and the first refractive portion 911, the light incident on the interface between the first refractive portion 911 and the second refractive layer 92 may tend to the normal line there, reducing the light with the incident angle greater than or equal to the critical angle incident on the interface between the first refractive portion 911 and the second refractive layer 92, thereby reducing the total reflection at the interface between the first refractive portion 911 and the second refractive layer 92, increasing the light emitted to the second refractive layer 92, and improving the light extraction efficiency of the pixel there, thereby improving the display effect of the display panel 100.

The second refractive layer 92 provided in one embodiment of the present disclosure may be multiplexed as an organic layer in the packaging structure of the display panel 100. To avoid the formation of a water vapor erosion channel at the second refractive layer 92, the display panel 100 provided in the embodiment of the present disclosure may also include a third inorganic film 63 covering the second refractive layer 92.

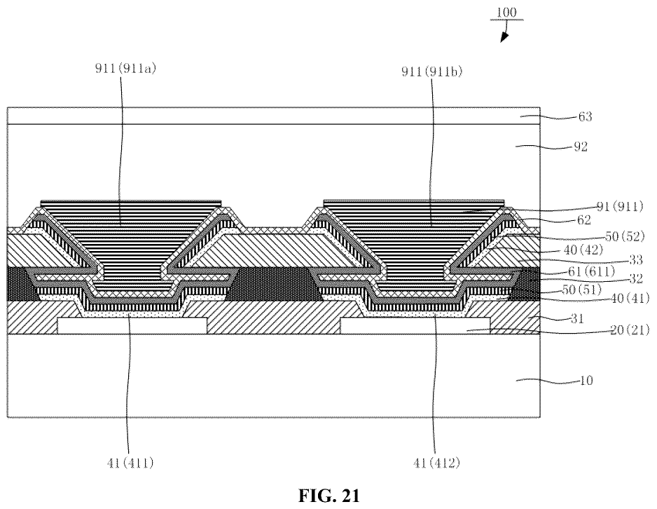

FIG. 21 illustrates a schematic diagram of the structure of another exemplary display panel 100 provided in one embodiment of the present disclosure. As shown in FIG. 21, the display panel 100 provided in one embodiment of the present disclosure may further include a third inorganic film 63. The third inorganic film 63 may be located on the side of the second refractive layer 92 away from the substrate 10, and the refractive index of the third inorganic film 63 may be less than the refractive index of the second refractive layer 92. It can be understood that the third inorganic film 63 provided in the embodiment of the present disclosure may cover the second refractive layer 92, may cover and block the water vapor erosion channel formed at the second refractive layer 92, and improve the packaging reliability of the display panel 100. Moreover, the refractive index of the third inorganic film 63 may be optimized to be less than the refractive index of the second refractive layer 92, and the light may be equivalent to being incident from a medium with a lower refractive index to a medium with a higher refractive index, thereby reducing the total reflection at the interface between the third inorganic film 63 and the second refractive layer 92 (refer to the principle of a medium with a lower refractive index incident to a medium with a higher refractive index shown in FIG. 18) , thereby increasing the light emitted to the third inorganic film 63, improving the light extraction efficiency of the pixel there, and thus improving the display effect of the display panel 100. In another embodiment, the structural layer for improving the light efficiency of the pixel may be a double-layer structure of the second inorganic film 62 and the first refractive layer 91; or may be a three-layer structure of the second inorganic film 62, the first refractive layer 91, and the second refractive layer 92; or may be a four-layer structure of the second inorganic film 62, the first refractive layer 91, the second refractive layer 92, and the third inorganic film 63; or more refractive layers may be provided to form more structural layers for improving the light efficiency of the pixel, and the present disclosure does not make any specific restrictions on this.

In some embodiments, the value difference in refractive index between the first refractive portion 911 and the second refractive layer 92 may be set to be different according to the wavelength of the first portion 41, so as to balance the light extraction efficiency of pixels of different color lights and improve the light extraction uniformity of the display panel 100. Continuing to refer to FIG. 18, the first portion 41 provided in the embodiment of the present disclosure may at least include a first color light portion 411 and a second color light portion 412, and the wavelength of the first color light portion 411 may be greater than the wavelength of the second color light portion 412. The first refractive portion 911 corresponding to the first color light portion 411 may be a first color light refractive portion 911a, and the first refractive portion 911 corresponding to the second color light portion 412 may be a second color light refractive portion 911b. The value difference between the refractive index of the first color light refractive portion 911a and the refractive index of the second inorganic film 62 may be greater than the value difference between the refractive index of the second color light refractive portion 911b and the refractive index of the second inorganic film 62. Because the light extraction efficiency of a pixel may be positively correlated with the refractive index difference, that is, the greater the refractive index difference, the greater the light extraction efficiency, and vice versa, the smaller the refractive index difference, the smaller the light extraction efficiency, the refractive index difference between the different color light refractive portions and the second inorganic film 62 may be set to be different, so that the light extraction efficiency of the pixels corresponding to the first color light portion 411 and the pixels corresponding to the second color light portion 412 may be balanced, the light extraction uniformity of the display panel 100 may be improved, the color deviation may be avoided, and the display effect of the display panel 100 may be improved.

That is to say, the wavelength of the first color light portion 411 provided in the embodiment of the present disclosure may be greater than the wavelength of the second color light portion 412. To improve the light extraction efficiency of the pixel corresponding to the first color light portion 411, so as to balance the light extraction efficiency of the pixel corresponding to the second color light portion 412, it may be necessary to set the refractive index difference between the first color light refractive portion 911a and the second inorganic film 62 to be greater than the difference between the refractive index of the second color light refractive portion 911b and the refractive index of the second inorganic film 62; and because the refractive index of the first refractive layer 91 may be greater than the refractive index of the second inorganic film 62, the greater the refractive index of the first refractive portion 911, the greater the difference in refractive index between the first refractive portion 911 and the second inorganic film 62. Therefore, the refractive index of the first color light refractive portion 911a provided in the embodiment of the present disclosure may be greater than the refractive index of the second color light refractive portion 911b, which may increase the refractive index difference between the first color light refractive portion 911a and the second inorganic film 62, and improves the light extraction efficiency of the pixel corresponding to the first color light portion 411.

In another embodiment, the first portion 41 may include a red light portion, a green light portion and a blue light portion. The red light portion may correspond to the first refractive portion 911 as a red light refractive portion, the green light portion may correspond to the first refractive portion 911 as a green light refractive portion, and the blue light portion may correspond to the first refractive portion 911 as a blue light refractive portion. Among them, the wavelength of the red light portion may be greater than the wavelength of the green light portion, and the wavelength of the green light portion may be greater than the wavelength of the blue light portion. Therefore, to balance the light extraction efficiency of the pixels corresponding to the red light portion, the green light portion and the blue light portion, the embodiment of the present disclosure may set the refractive index of the red light refractive portion to be greater than the refractive index of the blue light refraction portion and the green light refractive portion, and the refractive index of the green light refraction portion may be greater than the refractive index of the blue light refraction portion, or the refractive index of the green light refraction portion may be set to be equal to the refractive index of the blue light refractive portion, which may need to be specifically designed according to the actual application.

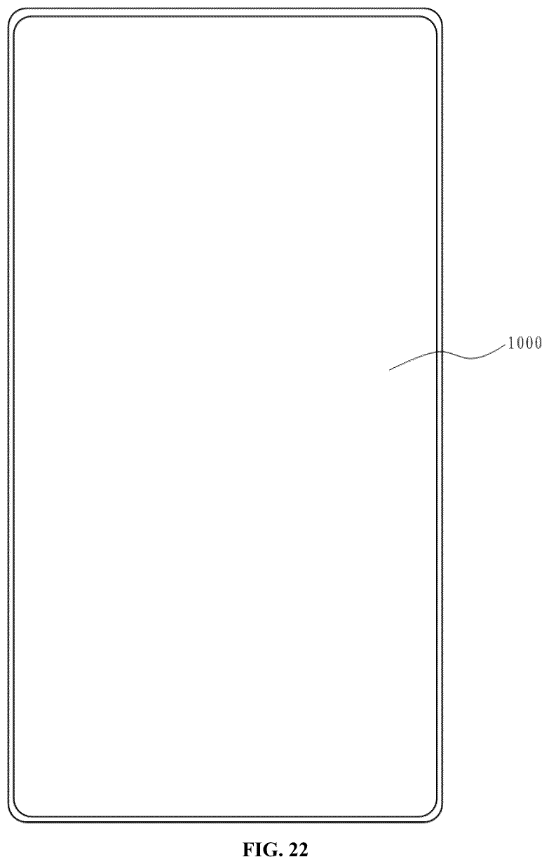

The present disclosure also provides an electronic device. FIG. 22 illustrates a schematic diagram of the structure of an exemplary electronic device 1000 according to various embodiments of the present disclosure. As shown in FIG. 22, the electronic device 1000 provided in one embodiment of the present disclosure may include a display panel 100 provided in any of the above embodiments.

In some embodiments, the electronic device 1000 may be a mobile terminal, a notebook, a tablet computer, a computer, a wearable device, or a vehicle-mounted display device, etc., and the present disclosure does not make any specific restrictions on this.

In summary, the present disclosure provides a display panel and an electronic device. The display panel may include a substrate and an anode layer. The anode layer may be located on the substrate, and the anode layer may include a plurality of anode blocks. The display panel may also include a first pixel definition layer. The first pixel definition layer may be located on a side of the anode layer away from the substrate, and the pixel definition layer may include a first pixel opening corresponding to the anode block. Further, the display panel may include an electrode connection layer. The electrode connection layer may be located on a side of the pixel definition layer away from the substrate, and the electrode connection layer may include a second pixel opening corresponding to the first pixel opening. Further, the display panel may include a second pixel definition layer. The second pixel definition layer may be located on a side of the electrode connection layer away from the substrate, and the second pixel definition layer may include a third pixel opening corresponding to the second pixel opening. Further, the display panel may include a light-emitting functional layer. The light-emitting functional layer may include a plurality of first portions and a plurality of second portions. The first portion may be at least located in the first pixel opening, and the second portion may at least cover the sidewall of the third pixel opening. Further, the display panel may include a cathode layer. The cathode layer may include a first cathode portion and a second cathode portion. The first cathode portion may cover the first portion and extend to contact the electrode connection layer. Further, the display panel may include a first inorganic film. The first inorganic film may be located on the side of the cathode layer away from the substrate. Further, the display panel may include a second inorganic film. The second inorganic layer may be located on the side of the first inorganic film away from the substrate, and the second inorganic film may cover the first inorganic film.

It can be seen from the above content that the technical solution provided by the embodiments of the present disclosure, the display panel may include a superposition structure of a first pixel definition layer, an electrode connection layer and a second pixel definition layer, and the first pixel opening, the second pixel opening and the third pixel opening based on the superposition structure and formed by the superposition structure, the light-emitting functional layer may be formed without a fine metal mask, so as not to be affected by the related problems brought by the FMM process. In addition, the display panel may also include a second inorganic film covering the first inorganic film, when a water vapor erosion channel occurs at the first inorganic film, it may be covered and blocked by the second inorganic film, thereby reducing the risk of the display panel being susceptible to water vapor erosion and improving the packaging reliability of the display panel.

In the description of the embodiments of the present disclosure, it should be understood that the orientation or position relationship indicated by the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, or “circumferential”, etc. is based on the orientation or position relationship shown in the drawings, which is only for the convenience of describing the embodiments of the present disclosure and simplifying the description, rather than indicating or implying that the device or element referred to must have a specific orientation, be constructed and operated in a specific orientation, and therefore cannot be understood as a limitation to the present application.

In addition, the terms “first” and “second” are only used for descriptive purposes, and cannot be understood as indicating or implying relative importance or implicitly indicating the number of technical features indicated. Thus, the features defined as “first” and “second” may explicitly or implicitly include at least one of the features. In the description of the embodiments of the present disclosure, “multiple” means at least two, such as two, three, etc., unless otherwise clearly defined.

In the embodiments of the present disclosure, unless otherwise clearly defined, the terms “installed”, “connected”, “connected”, “fixed” and the like should be understood in a broad sense, for example, it can be a fixed connection, a detachable connection, or an integral body; it can be a mechanical connection, an electrical connection or communication with each other; it can be directly connected, or indirectly connected through an intermediate medium, it can be the internal connection of two elements or the interaction relationship between two elements, unless otherwise clearly defined. For ordinary technicians in this field, the specific meanings of the above terms in this application can be understood according to the specific circumstances.

In the embodiments of the present disclosure, unless otherwise clearly defined, the first feature “above” or “below” the second feature may be that the first and second features are in direct contact, or the first and second features are in indirect contact through an intermediate medium. Moreover, the first feature “above”, “on” and “over” the second feature may be that the first feature is directly above or obliquely above the second feature, or simply means that the first feature is higher in level than the second feature. The first feature being “under”, “beneath” and “below” the second feature may mean that the first feature is directly below or obliquely below the second feature, or may simply mean that the first feature is less horizontally than the second feature.

In the embodiments of the present disclosure, if the terms “one embodiment”, “some embodiments”, “example”, “specific example”, or “some examples” appear, it may mean that the specific features, structures, materials or characteristics described in conjunction with the embodiment or example are included in at least one embodiment or example of the present disclosure. In this specification, the schematic representation of the above terms does not necessarily refer to the same embodiment or example. Moreover, the specific features, structures, materials or characteristics described may be combined in any one or more embodiments or examples in a suitable manner. In addition, in the absence of contradiction, a person skilled in the art may combine and combine different embodiments or examples and features of different embodiments or examples described in this specification.

Although the embodiments of the present disclosure have been shown and described above, it can be understood that the above embodiments are exemplary and cannot be understood as limitations on the present disclosure. A person of ordinary skill in the art may change, modify, replace and modify the above embodiments within the scope of the present disclosure.

What is claimed is:

1. A display panel, comprising:
a substrate;
an anode layer located on the substrate and including a plurality of anode blocks;
a first pixel definition layer located on a side of the anode layer away from the substrate and including a first pixel opening corresponding to an anode block of the plurality of anode blocks;
an electrode connection layer located on a side of the pixel definition layer away from the substrate and including a second pixel opening corresponding to the first pixel opening;
a second pixel definition layer located on a side of the electrode connection layer away from the substrate and including a third pixel opening corresponding to the second pixel opening;
a light-emitting functional layer including a plurality of first portions and a plurality of second portions, wherein a first portion of the plurality of first portions is at least located in the first pixel opening, and a second portion of the plurality of second portions at least covers a sidewall of the third pixel opening;
a cathode layer including a first cathode portion and a second cathode portion, wherein the first cathode portion covers the first portion and extends to contact the electrode connection layer;
a first inorganic film located on a side of the cathode layer away from the substrate; and
a second inorganic film is located on a side of the first inorganic film away from the substrate and covering the first inorganic film.

2. The display panel according to claim 1, comprising:
an organic film located on a side of the second inorganic film away from the substrate; and
a third inorganic film located on a side of the organic film away from the substrate.

3. The display panel according to claim 1, wherein the first inorganic film comprises:
a plurality of inorganic film blocks covering the first cathode portion and extending to cover a side of the second cathode portion away from the second cathode portion.

4. The display panel according to claim 1, comprising:
a display area and a frame area surrounding at least a portion of the display area, wherein the second inorganic film covers the display area and extends to cover the frame area.

5. The display panel according to claim 4, wherein:
the frame area includes at least one retaining wall arranged in a direction surrounding the display area; and
the second inorganic film covers the display area and extends to cover outside the at least one retaining wall.

6. The display panel according to claim 1, wherein:
the electrode connection layer exposes a surface of the first pixel definition layer away from the substrate; and
a bottom surface of the second pixel definition layer facing the substrate extends outside a surface of the electrode connection layer away from the substrate.

7. The display panel according to claim 1, further comprising:
a color resist layer located on a side of the second inorganic film away from the substrate, wherein the color resist layer includes a plurality of color resist portions, and the color resist portions are arranged corresponding to the plurality of first portions.

8. The display panel according to claim 7, further comprising:
an organic film located on a side of the second inorganic film away from the substrate; and
a third inorganic film located on a side of the organic film away from the substrate,
wherein a color resist portion of the plurality of color resist portions is located between the second inorganic film and the organic film.

9. The display panel according to claim 8, wherein:
the second pixel definition layer is a black matrix.

10. The display panel according to claim 7, further comprising:
an organic film located on a side of the second inorganic film away from the substrate; and
a third inorganic film located on a side of the organic film away from the substrate,
wherein:
a color resist portion of the plurality of color resist portions is located on a side of the third inorganic film away from the substrate;
the display panel also includes a black matrix located on a side of the third inorganic film away from the substrate; and
the black matrix surrounds the color resist portion.

11. The display panel according to claim 7, wherein:
the first portion at least includes a first color light portion and a second color light portion, and a wavelength of the first color light portion is greater than a wavelength of the second color light portion;
the color resist portion corresponding to the first color light portion is a first color light color resist portion, and the color resist portion corresponding to the second color light portion is a second color light color resist portion; and
in a direction perpendicular to a plane where the display panel is located, a thickness of the first color light color resist portion is greater than a thickness of the second color light color resist portion.

12. The display panel according to claim 1, further comprising:
a first refractive layer located on a side of the second inorganic film away from the substrate, wherein the first refractive layer includes a plurality of first refractive portions, the first refractive portions are arranged corresponding to the plurality of first portions, and a refractive index of the first refractive layer is different from a refractive index of the second inorganic film.

13. The display panel according to claim 12, wherein:
the refractive index of the first refractive layer is greater than the refractive index of the second inorganic film.

14. The display panel according to claim 13, further comprising:
a second refractive layer located on a side of the first refractive layer away from the substrate, wherein a refractive index of the second refractive layer is less than the refractive index of the first refractive layer.

15. The display panel according to claim 13, further comprising:
a third inorganic film located on a side of the second refractive layer away from the substrate, wherein a refractive index of the third inorganic film is less than the refractive index of the second refractive layer.

16. The display panel according to claim 12, wherein:
a first portion at least includes a first color light portion and a second color light portion, and a wavelength of the first color light portion is greater than a wavelength of the second color light portion;
the first refractive portion corresponding to the first color light portion is a first color light refractive portion, and the first refraction portion corresponding to the second color light portion is a second color light refractive portion; and
a value difference between the refractive index of the first color light refractive portion and the refractive index of the second inorganic film is greater than a value difference between the refractive index of the second color light refraction portion and the refractive index of the second inorganic film.

17. The display panel according to claim 16, wherein:
the refractive index of the first refractive layer is greater than the refractive index of the second inorganic film; and
the refractive index of the first color light refractive portion is greater than the refractive index of the second color light refraction portion.

18. The display panel according to claim 1, wherein:
at least one of the first inorganic film and the second inorganic film is a SiOx film, a SiNx film or a stacked film of SiOx/SiOx.

19. An electronic device, comprising:
a display panel including:
a substrate;
an anode layer located on the substrate and including a plurality of anode blocks;
a first pixel definition layer located on a side of the anode layer away from the substrate and including a first pixel opening corresponding to an anode block of the plurality of anode blocks;
an electrode connection layer located on a side of the pixel definition layer away from the substrate and including a second pixel opening corresponding to the first pixel opening;
a second pixel definition layer located on a side of the electrode connection layer away from the substrate and including a third pixel opening corresponding to the second pixel opening;
a light-emitting functional layer including a plurality of first portions and a plurality of second portions, wherein a first portion of the plurality of first portions is at least located in the first pixel opening, and a second portion of the plurality of second portions at least covers a sidewall of the third pixel opening;
a cathode layer including a first cathode portion and a second cathode portion, wherein the first cathode portion covers the first portion and extends to contact the electrode connection layer;
a first inorganic film located on a side of the cathode layer away from the substrate; and
a second inorganic film is located on a side of the first inorganic film away from the substrate and covering the first inorganic film.
